(19) United States
(12) Patent Application Publication
(10) Pub. No.: US 2026/0106604 A1
(43) Pub. Date: Apr. 16, 2026

(54) SPREAD SPECTRUM MODULATOR

(71) Applicant: TEXAS INSTRUMENTS INCORPORATED, Dallas, TX (US)

(72) Inventors: Sombuddha Chakraborty, Redwood City, CA (US); Pei-Hsin Liu, Bedford, NH (US); Bharath Kannan, Merrimack, NH (US); Stefan Herzer, Marzling (DE)

(21) Appl. No.: 18/914,650

(22) Filed: Oct. 14, 2024

(51) Int. Cl. H03K 5/1252; H02M 1/44; H03K 21/08

(52) U.S. Cl. CPC H03K 5/1252; H02M 1/44; H03K 21/08

(57) ABSTRACT

A circuit includes a switching converter, an oscillator, and a spread spectrum modulator (SSM). The oscillator has a modulation input and a clock output. The clock output is coupled to the switching converter. The oscillator is configured to generate a clock signal at the clock output having a frequency based on a modulation signal at the modulation input. The SSM has a modulation output coupled to the modulation input of the oscillator. The SSM is configured to generate the modulation signal at the modulation output while adjusting a rate of change of the modulation signal based on a magnitude of the modulation signal at a boundary of a modulation time period.

### BACKGROUND

A switching power converter includes or is coupled to an oscillator that produces a clock signal (clock) to control the state of the transistor switches within the switching power converter. For some switching power converters, the clock frequency is fixed. A fixed clock frequency can cause the switching power converter to generate electromagnetic interference (EMI) which may detrimentally impact other devices in the same system as the switching power converter. Spread spectrum modulation (SSM) is a technique by which the frequency of the clock varies over a period of time (modulation period). Varying the clock frequency may reduce the magnitude of the EMI generated by the switching power converter.

### SUMMARY

In one example, a circuit includes a switching converter, an oscillator, and a spread spectrum modulator (SSM). The oscillator has a modulation input and a clock output. The clock output is coupled to the switching converter. The oscillator is configured to generate a clock signal at the clock output having a frequency based on a modulation signal at the modulation input. The SSM has a modulation output coupled to the modulation input of the oscillator. The SSM is configured to generate the modulation signal at the modulation output while adjusting a rate of change of the modulation signal based on a magnitude of the modulation signal at a boundary of a modulation time period.

In another example, a circuit includes a switching converter, an oscillator, and an SSM. The oscillator has a modulation input and a clock output. The clock output is coupled to the switching converter. The oscillator is configured to generate a clock signal at the clock output having a frequency based on a modulation signal at the modulation input. The SSM has a modulation output coupled to the modulation input of the oscillator. The SSM is configured to generate the modulation signal at the modulation output while adjusting a rate of change of the modulation signal based on a magnitude of the modulation signal and a modulation clock signal.

In yet another example, a circuit includes an oscillator having a modulation input and a clock output. The oscillator is configured to generate a clock signal at the clock output having a frequency based on a modulation signal at the modulation input. A modulator has a modulation output coupled to the modulation input of the oscillator. The modulator is configured to generate the modulation signal at the modulation output while adjusting a rate of change of the modulation signal based on a magnitude of the modulation signal at a boundary of a modulation time period.

### BRIEF DESCRIPTION OF THE DRAWINGS

FIG. 1 is a block diagram of a power converter, in an example.

FIG. 2 is a waveform of an example clock frequency of the power converter.

FIG. 3 is a graph illustrating example reductions in average and peak electromagnetic interference relative to the modulation period of the power converter, in an example.

FIG. 4 is a block diagram of a power converter having an auto-tuning spread spectrum modulator, in another example.

FIGS. 5, 6, and 7 are waveforms illustrating the operation of the auto-tuning spread spectrum modulator of FIG. 4 for different duty cycle conditions, in various examples.

FIG. 8 is a schematic diagram of the auto-tuning spread spectrum modulator of FIG. 4, in an example.

FIG. 9 is a schematic diagram of the auto-tuning spread spectrum modulator of FIG. 4, in another example.

### DETAILED DESCRIPTION

The same reference numbers or other reference designators are used in the drawings to designate the same or similar (either by function and/or structure) features.

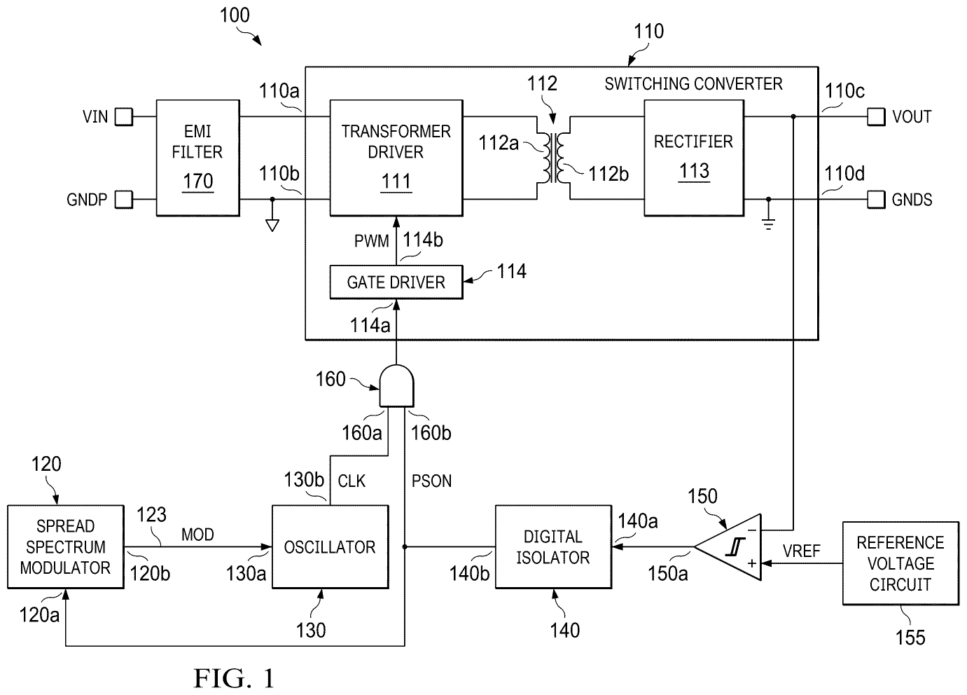

FIG. 1 is a schematic diagram of a power converter 100, in an example. Power converter 100 converts an input voltage VIN into an output voltage VOUT. In this example, power converter 100 includes a switching converter 110, a spread spectrum modulator (SSM) 120, an oscillator 130, a digital isolator 140, a comparator 150, a reference voltage circuit 155, an AND gate 160 (or other type of logic gate(s)), and an electromagnetic interference (EMI) filter 170. Switching converter 110 includes input terminals 110a and 110b and output terminals 110c and 110d. Input terminals 110a and 110b are coupled to the input voltage VIN and ground GNDP, respectively, via EMI filter 170. EMI filter 170 helps to reduce the magnitude of EMI generated by power converter 100.

Switching converter 110 in the example power converter 100 is an isolated switching converter including a transformer driver 111, an isolation circuit 112, a rectifier 113, and a gate driver 114. Accordingly, power converter 100 may be an isolation power converter. Transformer driver 111 is coupled to input terminals 110a and 110b. Transformer driver 111 may include one or more transistors (e.g., a half-bridge, a full bridge) driven by a pulse width modulation (PWM) signal from gate driver 114. Isolation circuit 112 is a transformer in the example of FIG. 1, and is referred to as transformer 112. In other examples, isolation circuit may be a different type of isolator such as an optical isolator or a capacitive isolator. The primary winding 112a of transformer 112 is coupled to transformer driver 111. The secondary winding 112b of transformer 112 is coupled to rectifier 113. The output of rectifier 113 is coupled to output terminals 110c and 110d to provide the output voltage VOUT and isolated ground GNDS, respectively. The input voltage VIN is converted into a time varying voltage by transformer driver 111, which transfers energy through the primary and secondary windings 112a and 112b to rectifier 113. Rectifier 113 then rectifies the voltage from the secondary winding 112b into the output voltage VOUT.

SSM 120 has a control input 120a and a modulation output 120b. Oscillator 130 has a modulation input 130a and a clock output 130b. AND gate 160 has inputs 160a and 160b and an output. Comparator 150 has a negative (−) input, a positive (+) input, and an output 150a. Digital isolator 140 has an input 140a and an output 140b. Output 140b of digital isolator 140 is coupled to input 160b of AND gate 160 and to the control input 120a of SSM 120. Modulation output 120b of SSM 120 is coupled to the modulation input 130a of oscillator 130. The clock output 130b of oscillator 130 is coupled to the input 160a of AND gate 160. The output of AND gate 160 is coupled to an input 114a of gate driver 114. An output 114b of gate driver 114 is coupled to transformer driver 111.

The output terminal 110c is coupled to the negative input of comparator 150. A reference voltage VREF, generated by reference voltage circuit 155, is provided to the positive input of comparator 150. The output signal from comparator 150 will be logic high if output voltage VOUT is below the reference voltage VREF, and logic low if output voltage VOUT is above the reference voltage VREF. The output signal from comparator 150 is provided through digital isolator 140 as signal PSON to AND gate 160 and to the control input 120a of SSM 120.

Switching converter 110 is on or off based on the logic state of signal PSON from the output 140b of digital isolator 140. In the example of FIG. 1, switching converter 110 turns on when signal PSON is logic high and turns off when signal PSON is logic low. When signal PSON is logic high, the clock signal (CLK) from oscillator 130 is provided through AND gate 160 to the gate driver 114 to switch the transistor switches within the transformer driver 111 on and off based on the clock signal CLK. When switching converter 110 is on, energy is transferred across isolation circuit 112 and the output voltage VOUT increases (e.g., linearly). When the output voltage VOUT rises above the reference voltage VREF, the output signal from comparator 150 becomes logic low, and signal PSON also is forced low. With signal PSON at a logic low level, switching converter 110 turns off and output voltage VOUT decreases.

When signal PSON is logic high, SSM 120 generates a modulation signal MOD 123 which is provided to oscillator 130. In one example, modulation signal MOD 123 is a digital signal that increases and decreases in approximately a triangular shape. In another example, modulation signal MOD 123 is an analog signal (e.g., a voltage) having a triangular waveform. Modulation signal MOD 123 causes oscillator 130 to vary the frequency of the clock signal CLK to also have a triangular shape.

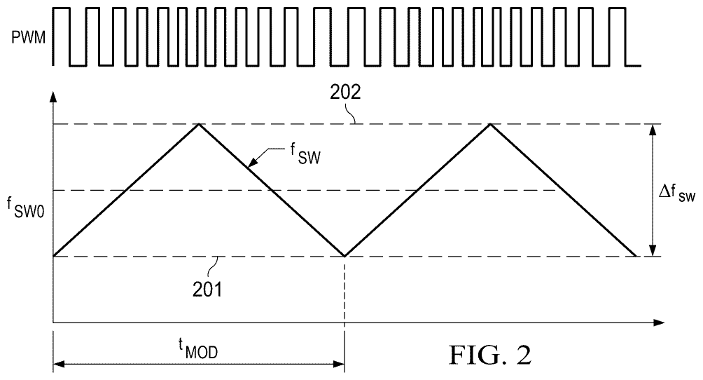

FIG. 2 includes example waveforms of the frequency (f_{SW0}) of the clock signal CLK and the corresponding PWM signal from gate driver 114. The frequency of the clock signal CLK has an approximately triangular profile varying from a lower frequency 201 to an upper frequency 202 and back down to the lower frequency 201 over a modulation period t_{MOD}. The difference between the upper frequency 202 and the lower frequency 201 is the delta frequency Δf_{SW}. Gate driver 114 receives the clock signal CLK whose frequency profile is shown in FIG. 2 and produces the corresponding PWM signal. At higher frequencies of clock signal CLK, the frequency of the PWM signal is higher than at lower frequencies of the clock signal.

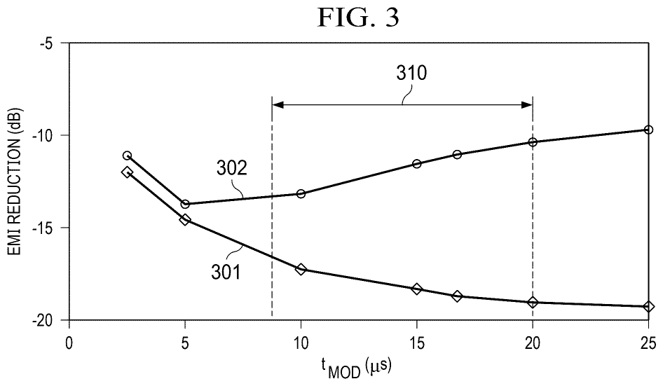

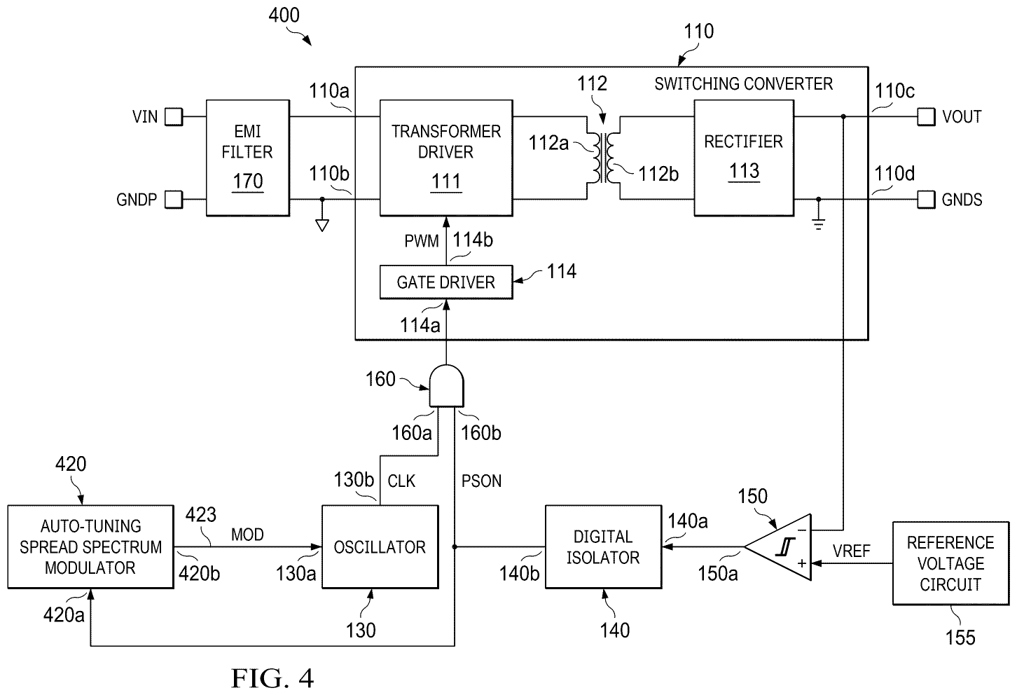

FIG. 3 includes graphs 301 and 302 of the average reduction in EMI as a function of the modulation period t_{MOD}. EMI can be calculated as an average value or as a peak value. Graph 301 corresponds to the EMI reduction of the average EMI level. Graph 302 corresponds to the EMI reduction of the peak value of the EMI. As the modulation period t_{MOD} increases, the reduction in the average EMI value decreases. With increasing modulation period, however, the reduction in the peak EMI value initially decreases between a modulation period of approximately 3 microseconds to approximately 5 microseconds. Above a modulation period of 5 microseconds, the reduction in the peak EMI value then increases. Above a modulation period of, for example, 20 microseconds, while the reduction in the average EMI value is advantageously low, the peak EMI value is undesirably high while the reduction in the peak EMI value is undesirably low. Range 310 of the modulation period is shown in FIG. 3 and discussed below with respect to FIG. 4.

FIG. 4 is schematic diagram of a power converter 400 in which the spread spectrum modulator is auto-tuning spread spectrum modulator (SSM) 420. Auto-tuning SSM 420 addresses the problem described above by dynamically causing the rate of change of the frequency of the clock signal CLK to vary so as to maintain a modulation period t_{MOD} within a range 310 (FIG. 3). In one example, range 310 of the modulation period is from 8 microseconds to 20 microseconds. Below 8 microseconds, the reduction in both the average and peak EMI is unacceptably small, and above 20 microseconds, the reduction in the peak EMI is unacceptably small. By dynamically adjusting the modulation frequency of the change in the frequency of the clock signal CLK across a modulation period that is within range 310, the reduction in both the average and peak EMI is above a target level.

Power converter 400 of FIG. 4 is largely the same as power converter 100 of FIG. 1. A difference between the two power converters is that power converter 400 includes an auto-tuning SSM 420 whereas SSM 120 of power converter 100 does not have an auto-tuning capability. Auto-tuning SSM 420 has a control input 420a and a modulation output 420b. The output 140b of digital isolator 140 is coupled to the control input 420a of auto-tuning SSM 420. The modulation output 420b of auto-tuning SSM 420 is coupled to the modulation input 130a of oscillator 130. Auto-tuning SSM 420 dynamically adjusts the rate of change of modulation signal MOD 423 such that the modulation period of the clock signal CLK is within a target range, e.g., 8 microseconds to 20 microseconds. In one example, modulation signal MOD 423 is a voltage such as a ramp voltage that is used by oscillator 120 to adjust the frequency of clock signal CLK.

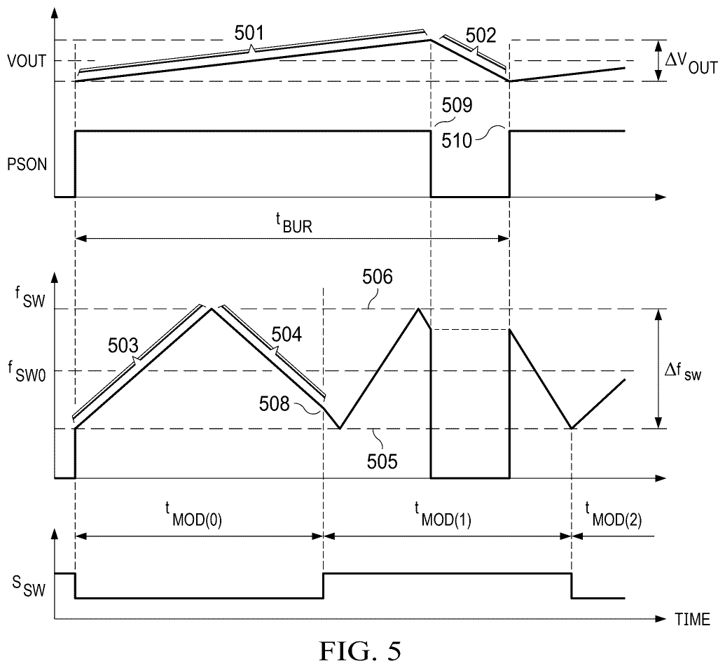

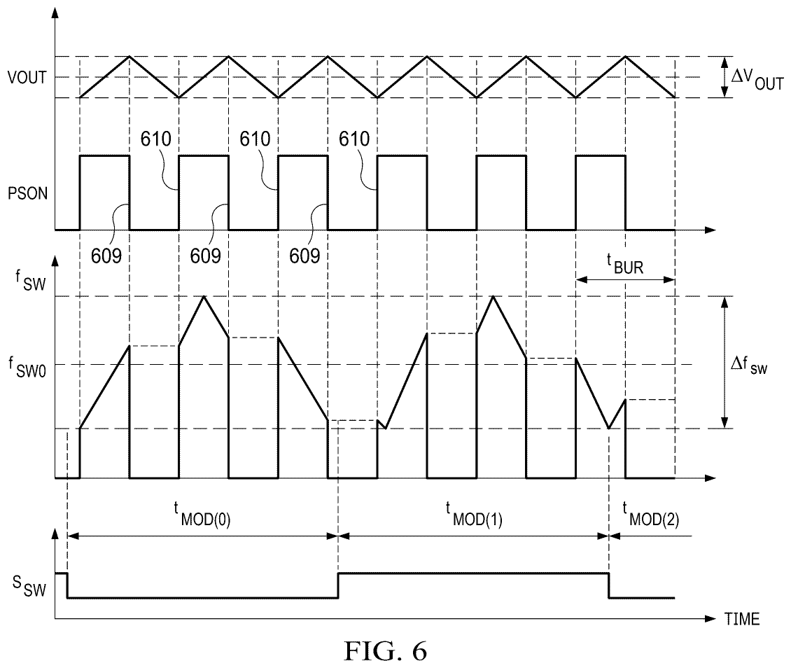

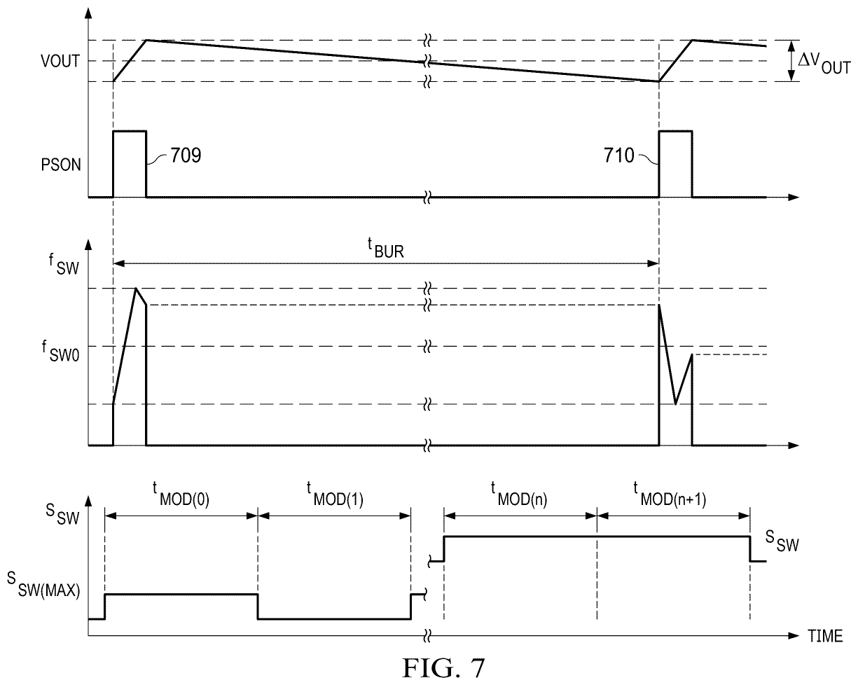

FIGS. 5, 6, and 7 are example waveforms for the output voltage VOUT, signal PSON, the frequency (f_{SW0}) of the clock signal CLK, and a waveform S_{SW} illustrating a higher duty cycle condition (FIG. 5), a medium duty cycle condition (FIG. 6), and a lower duty cycle condition (FIG. 7). The waveform S_{SW} refers to the slope of the rising and falling edges of the triangular waveform for f_{SW0}—a higher value of S_{SW} means that the absolute value of the slope of f_{SW0} is higher than a lower value of S_{SW}. Referring first to FIG. 5, the higher duty cycle condition is reflected by signal PSON being high for a majority of each burst time period (t_{BUR}). While signal PSON is logic high, the switching converter 110 is on and transferring power through the isolation circuit 112. Accordingly, the output voltage VOUT increases as shown at 501. While signal PSON is logic low, switching converter 110 is off and the output voltage VOUT decreases as shown at 502. The difference between the upper level of the output voltage VOUT and its lower level is ΔVOUT.

While signal PSON is logic high, oscillator 130 responds to the modulation signal MOD 423 by causing the frequency f_{SW0} of the clock signal CLK to increase and decrease as shown at 503 and 504 at a rate based on the rate (e.g., the slope) at which the modulation signal MOD increases and decreases. Auto-tuning SSM 420 implements a modulation period (t_{MOD}) that is within a target range (e.g., 8 microseconds to 20 microseconds). At the beginning of modulation period 0 t_{MOD(0)}, the frequency of clock signal CLK is at a lower frequency 505. During modulation period t_{MOD(0)}, auto-tuning SSM 420 generates the modulation signal MOD 423 to increase and then decrease. In response to the increasing modulation signal MOD 423, oscillator 130 generates the clock signal CLK to have an increasing clock frequency as shown at 503. Then, auto-tuning SSM 420 changes the direction of the modulation signal MOD 423 and the modulation signal MOD 423 decreases. The frequency of the clock signal CLK peaks at an upper frequency 506, and then decreases as shown at 504 based on the decreasing modulation signal MOD 423.

Auto-tuning SSM 420 determines the magnitude of the modulation signal MOD 423 at the end of modulation period 0 t_{MOD(0)} at time point 508. At time point 508, the modulation signal MOD 423 has not yet reached the level that it had at the beginning of the modulation period 0 t_{MOD(0)} and, accordingly, the frequency f_{SW0} of the clock signal CLK has not yet returned to the lower frequency 505. In response to determining that the modulation signal MOD 423 (and frequency F_{SW0} of the clock signal CLK) have not yet returned to their initial levels at the beginning of the modulation period, auto-tuning SSM 420 responds by increasing the rate of change of the modulation signal MOD 423 during the next modulation period, which is modulation period 1 (t_{MOD(1)} ). This process continues until the value of the modulation signal MOD 423 (and the frequency of the clock signal CLK) at the end of each modulation period approximately match the value of the modulation signal MOD 423 (and clock frequency) at the beginning of the modulation period.

Another benefit of auto-tuning SSM 420 is shown in FIG. 5. When the PSON signal transitions to a logic low level at falling edge 509 to turn off switching converter 110, the value of the modulation signal MOD 423 is captured so that at the next rising edge 510 of the PSON signal, oscillator 130 receives the same value of the modulation signal and continues by generating the same clock frequency as was the case when switching converter 110 was previously turned off. By freezing the value of the modulation signal MOD 423 at the end of each modulation period and changing the modulation signal MOD only when the power converter is switching, switching converter 110 can fully utilize the entire frequency modulation range across different duty-cycles while also avoiding abrupt changes in the switching frequency.

FIG. 6 represents the same concept as described above regarding FIG. 5 but for a modulation period (t_{MOD}) that is longer than the burst time period (t_{BUR}). In the example of FIG. 6, the modulation period spans three burst periods. The value of the modulation signal MOD 423 at the rising edge 610 of the PSON signal is the value that the modulation signal MOD had at the previous falling edge 609 of the PSON signal, as described above. Auto-tuning SSM 420 determines the value of the modulation signal MOD at the end of each modulation period and adjusts the rate of change of the modulation signal MOD to either increase the rate or decrease the rate so as to incrementally cause the period of the modulation signal MOD to approximately match the target period (e.g., 8 microseconds to 20 microseconds).

FIG. 7 represents the same concept as described above regarding FIGS. 5 and 6 but for a relatively low duty cycle condition. The value of the modulation signal MOD 423 at the rising edge 710 of the PSON signal is the value that the modulation signal MOD had at the previous falling edge 709 of the PSON signal, as described above. As described above, auto-tuning SSM 420 determines the value of the modulation signal MOD at the end of each modulation period and adjusts the rate of change of the modulation signal MOD to either increase the rate or decrease the rate so as to incrementally cause the period of the modulation signal MOD to approximately match the target period (e.g., 8 microseconds to 20 microseconds).

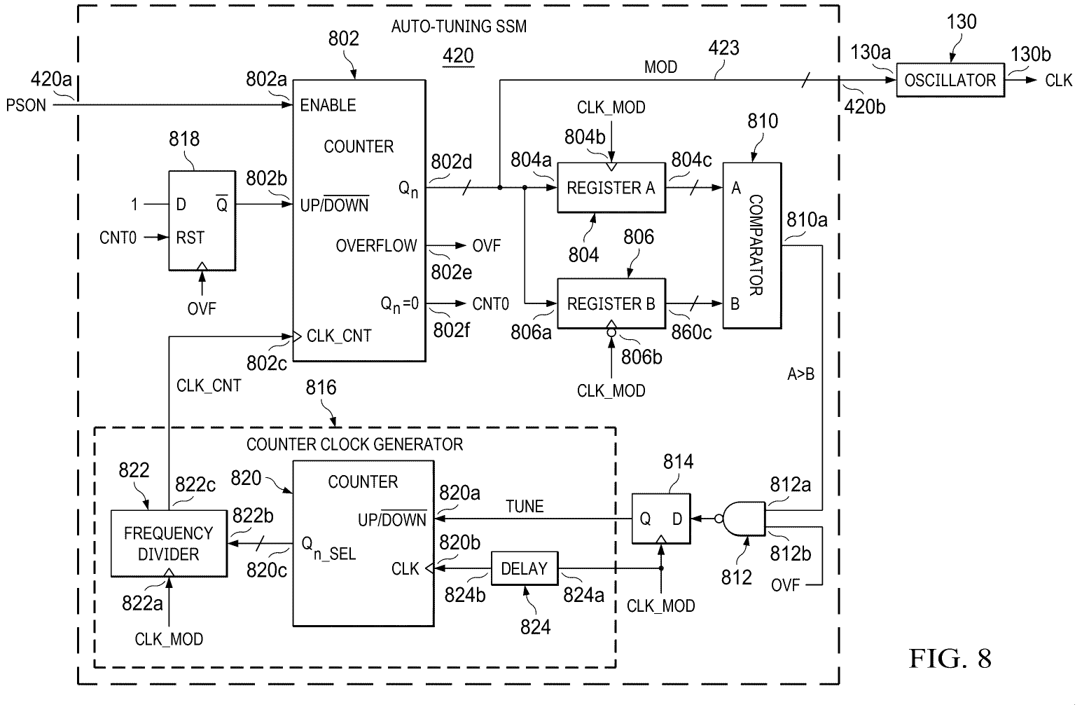

FIG. 8 is a schematic diagram of auto-tuning SSM 420, in accordance with an example. In this example, auto-tuning SSM 420 includes a counter 802, a register A 804, a register B 806, a comparator 810, a NAND gate 812, flip-flops 814 and 818, and a counter clock generator 816. In the example of FIG. 8, counter 802 is an up/down counter, and comparator 810 is a digital comparator. Counter 802 has an enable input 802a, a control input 802b, a clock input 802c, a counter output 802d, an overflow output 802e, and a count equal zero output 802f. Counter output 802d is coupled to the modulation output 420b and to a register input 804a of register A 804 and to a register input 806a of register B 806. Register A 804 has a clock input 804b and a register output 804c. Similarly, register B 806 has a clock input 806b and a register output 806c. The clock input 806b is an inverted clock input relative to the clock input 804b. A modulation clock signal CLK_MOD, e.g., generated within auto-tuning SSM 420, is coupled to the clock inputs 804b and 806b. In one example, a rising edge of the modulation clock signal CLK_MOD causes register A 804 to store the digital value Q₀ from the counter output 802d of counter 802, and a falling edge of the modulation clock signal CLK_MOD causes register B 806 to store the digital value Q₀ from the counter output 802d. The output 804c of register A 804 is coupled to an input A of comparator 810, and the output 806c of register B 806 is coupled to an input B of comparator 810. Comparator 810 compares the digital values from registers A and B and produces an A>B signal at the output 810a. In one example, if the digital value from register A 804 is greater than the digital value from register B 806, comparator 810 asserts the A>B signal logic high, and if the digital value from register A 804 is smaller than the digital value from register B 806, comparator 810 asserts the A>B signal logic low.

Counter 802 asserts an overflow signal OVF logic high when the digital value at counter output 802d reaches its maximum value. The comparator output 810a is coupled to an input 812a of NAND gate 812, and the overflow output 802e is coupled to an input 812b of NAND gate 812. The output of NAND gate 812 is coupled to a data (D) input of flip-flop 814. A clock input of flip-flop 814 receives the modulation clock signal CLK_MOD.

Counter clock generator 816 includes a counter (e.g., an up/down counter) 820, a frequency divider 822, and a delay circuit 824. Counter 820 has a control input 820a, a clock input 820b, and a counter output 820c. The Q output of flip-flop 814 provides a signal TUNE and is coupled to the control input 820a of counter 820. Delay circuit 824 has an input 824a and an output 824b. The delay circuit's input 824a receives the modulation clock signal CLK_MOD, and the delay circuit's output 824b is coupled to the clock input 820b of counter 820. Frequency divider 822 has a clock input 822a, a control input 822b, and clock output 822c. The clock input 822a receives a clock signal CLK_HF, which may have a higher frequency than the modulation clock signal CLK_MOD. The counter output 820c is coupled to the control input 822b. Frequency divider 822 divides down its input clock signal CLK_HF by a factor selected by the output count value at counter output 820c of counter 820. In one example, frequency divider has a look-up table (LUT) indexed by the output count value form counter 820. The output clock signal from frequency divider 822 is clock signal CLK_CNT. The clock output 822c of frequency divider 822 is coupled to the clock input 802c of counter 802.

The D input of flip-flop 818 is tied to a logic high (“1”) signal. A reset (RST) input of D flip-flop 818 is coupled to the count equal zero output 802f of counter 802 and receives a signal CNT0 from counter 802. Counter 802 asserts the signal CNT0 to a logic high level when the digital value Qₙ from counter 802 equals 0 and asserts the signal CNT0 to a logic low level when the digital value Qₙ is other than 0. The overflow output 802e from counter 802 is coupled to a clock input of flip-flop 818. The Qbar (Q̅) output of flip-flop 818 is coupled to the control input 802b of counter 802.

When signal PSON is logic high, counter 802 is enabled and increments or decrements its digital value Qₙ upon a given edge (e.g., rising edge) of the clock count signal CLK_CNT from frequency divider 822. In one example, counter 802 increments its output digital value Qₙ if the signal from Qbar output of flip-flop 818 is logic high and decrements its output digital value Qₙ if the signal from Qbar output of flip-flop 818 is logic low. When the output digital value Qₙ reaches maximum value, counter 802 asserts the overflow signal OVF logic high, and when the output digital value Qₙ reaches zero, counter 802 asserts the signal CNT0 logic high.

Register A 804 is clocked upon a rising edge of the modulation clock signal CLK_MOD and, accordingly, stores the output digital value Qₙ from counter 802 at the beginning of each modulation time period. Register B 806 is clocked upon a falling edge of the modulation clock signal CLK_MOD and, accordingly, stores the output digital value Qₙ from counter 802 at the end of each modulation time period. The output digital value Qₙ from counter 802 is the modulation signal MOD 423. Comparator 810 compares the output digital values from counter 802 at the beginning and end of each modulation time period. The result of the comparison, the A>B signal, is inverted through NAND gate 812 upon the overflow signal OVF being logic high. Accordingly, if the A>B signal is logic high, the output signal from NAND gate 812 will be logic low and flip-flop 814 will latch its TUNE output signal to be logic low upon a rising edge of the modulation clock signal CLK_MOD. A logic low level for the TUNE output signal causes counter 820 to count down. Counter 820 is clocked by a delayed version of the modulation clock signal CLK_MOD via delay circuit 824. if the A>B signal is logic low, the output signal from NAND gate 812 will be logic high and flip-flop 814 will latch its TUNE output signal to be logic high upon a rising edge of the modulation clock signal CLK_MOD. A logic high for the TUNE output signal causes counter 820 to count up.

The incremented or decremented output count value from counter 820 causes frequency divider 822 to divide down its input clock signal CLK_HF by a different factor. A different frequency for the frequency divider's output clock signal CLK_CNT causes counter 802 to count up or down at a different rate thereby adjusting the rate of change of the modulation signal MOD 423.

The example circuitry for auto-tuning SSM 420 in FIG. 8 is a digital implementation that produces the modulation signal MOD 423 as a multi-bit digital signal. In this example, oscillator 130 is a digital oscillator. An example of a digital oscillator is a ring oscillator. Accordingly, oscillator 130 in FIG. 8 may be implemented as a ring oscillator.

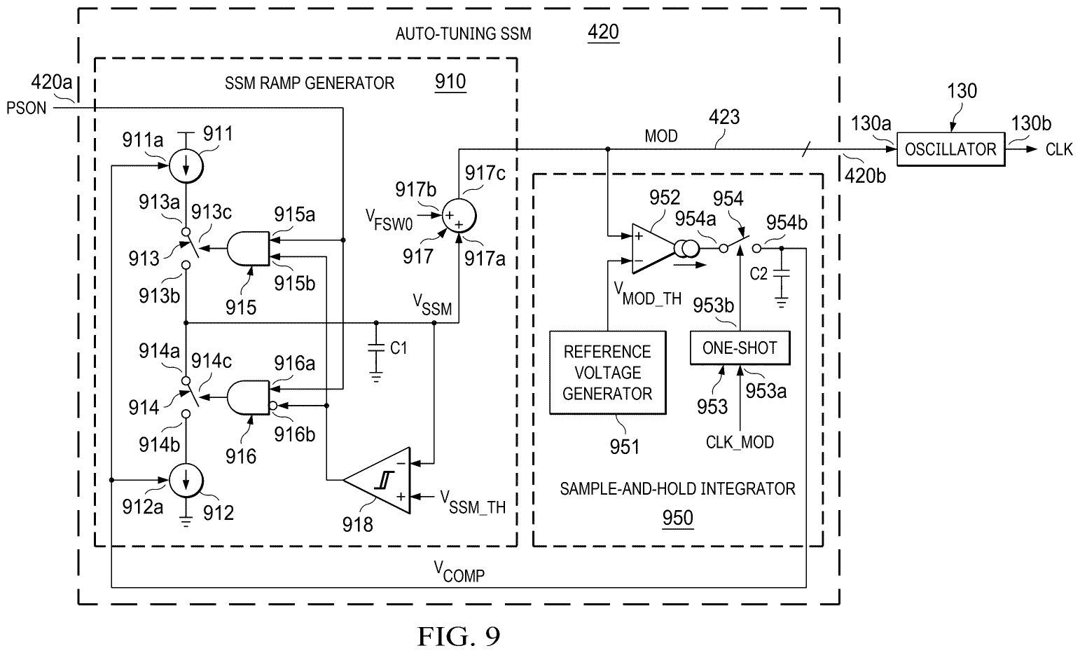

FIG. 9 is a schematic diagram of auto-tuning SSM 420 in another example. In this example, auto-tuning SSM 420 includes an SSM ramp generator 910 coupled to a sample-and-hold integrator 950. SSM ramp generator 910 includes current source circuits 911 and 912, switches 913 and 914 (e.g., transistors), AND gates 915 and 916, a capacitor C1, a voltage summer 917, and a comparator 918. Switch 913 has terminals 913a and 913b and a control input 913c. Switch 914 has terminals 914a and 914b and a control input 914c. Terminal 913a is coupled to current source circuit 911. Terminals 913b and 914a are coupled together and to a terminal of capacitor C1 and an input 917a of voltage. summer 917. The other terminal of capacitor C1 is coupled to ground. In one example, current source circuits 911 and 912 are voltage-controlled current sources. Accordingly, current source circuits 911 and 912 have control inputs 911a and 912a, respectively. Current sources 911 and 912 generate a current proportional to the voltage provided at their respective control inputs 911a, 912a. Control input 420a of auto-tuning SSM 420 is coupled to inputs 915a and 916a of AND gates 915 and 916, respectively. The output of comparator 918 is coupled to inputs 915b and 916b of AND gates 915 and 916, respectively. In this example, input 916b of AND gate 916 is an inverted input. The output of AND gate 915 is coupled to the control input 913c of switch 913. The output of AND gate 916 is coupled to the control input 914c of switch 914. Capacitor C1 is also coupled to the negative input of comparator 918. The voltage across capacitor C1 is voltage V_{SSM}. A threshold voltage, V_{SSM_TH}, is provided to the positive input of comparator 918. A voltage V_{FFSW0} may be generated by, for example, a bandgap reference circuit. The voltage V_{FFSW0} may be correlated with the switching frequency without SSM at the output 130b of oscillator 130 and is provided to input 917b of voltage summer 917. The output 917c of voltage summer 917 is coupled to the modulation output 420b and provides the modulation signal MOD 423. In this example, the modulation signal MOD 423 is an analog signal (e.g., a voltage), and oscillator 130 is an analog oscillator such as a voltage-controlled oscillator. Oscillator 130 generates the clock signal CLK with a frequency that is proportional to the magnitude of the modulation signal 423.

Sample-and-hold integrator 950 includes a reference voltage generator 951, a transconductance amplifier 952, a one-shot circuit 953, a switch 954 (e.g., a transistor), and a capacitor C2. The positive input of transconductance amplifier 952 is coupled to the output 917c of voltage summer 917 and the modulation output 420b of auto-tuning SSM 420. The output of reference voltage generator 951 provides a reference voltage V_{MOD_TH} and is coupled to the negative input of transconductance amplifier 952. The output of transconductance amplifier 952 is coupled to a terminal 954a of switch 954. The other terminal 954b of switch 954 is coupled to a capacitor C2 and to the control inputs 911a and 912a of current source circuits 911 and 912, respectively. The voltage across capacitor C2 is voltage V_{COMP} and is provided to the control inputs 911a and 912a of current source circuits 911 and 912, respectively. One-shot circuit 953 receives the modulation clock signal CLK_MOD. The output of one-shot circuit 953 is coupled to a control input of switch 954.

Modulation signal 423 is a voltage that ramps up when switch 913 closes and current from current source circuit 911 charges capacitor C1 and that ramps down when switch 914 closes and capacitor C1 discharges through current source circuit 912. The magnitude of the charging current to and discharging current from capacitor C1 is controlled by the voltage V_{COMP}, which is provided to the control inputs 911a and 912a of the respective voltage-controlled current sources 911 and 912. The difference between the modulation signal 423 and the threshold voltage VMOD_TH is amplified and converted to a current by transconductance amplifier 952. The resulting current from transconductance amplifier 952 charges capacitor C2 during a pulse generated by one-shot circuit 953 upon each rising edge of the modulation clock signal CLK_MOD. Accordingly, voltage V_{COMP} is proportional to the difference between the modulation signal 423 and the threshold voltage VMOD_TH. In the example of FIG. 9, a larger difference between the modulation signal 423 and the threshold voltage VMOD_TH causes voltage V_{COMP} across capacitor C2 to be larger, which causes the current source circuits 911 and 912 to increase the current produced therefrom. The rate of change of the modulation signal MOD 423 thereby increases. Similarly, a smaller difference between the modulation signal 423 and the threshold voltage VMOD_TH causes voltage V_{COMP} to be smaller, which causes the current source circuits 911 and 912 to decrease the current produced therefrom. The rate of change of the modulation signal MOD 423 thereby decreases.

In some examples, the modulation signal 423 is a triangular wave. The currents produced by current source circuits 911 and 912 may be approximately the same for a given level of voltage VCOMP thereby causing the modulation signal 423 to be a triangular wave. In other examples, the modulation signal 423 is a sawtooth wave. The currents produced by current source circuits 911 and 912 may be different for a given level of voltage VCOMP producing causing the modulation signal 423 to be a sawtooth wave. For example, to cause the modulation signal MOD 423 to be a sawtooth wave, the discharge current produced by current source circuit 912 may be larger than the charge current produced by current source circuit 911.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

Also, in this description, the recitation “based on” means “based at least in part on. ” Therefore, if X is based on Y, then X may be a function of Y and any number of other factors.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal”, “node”, “interconnection”, “pin” and “lead” are used interchangeably. Unless specifically stated to the contrary, these terms are generally used to mean an interconnection between or a terminus of a device element, a circuit element, an integrated circuit, a device or other electronics or semiconductor component.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

Circuits described herein are reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately” or “substantially” preceding a parameter means being within +/−10 percent of that parameter or, if the parameter is zero, a reasonable range of values around zero.

Modifications are possible in the described examples, and other examples are possible, within the scope of the claims.

What is claimed is:

1. A circuit, comprising:
a switching converter;
an oscillator having a modulation input and a clock output, the clock output coupled to the switching converter, the oscillator configured to generate a clock signal at the clock output having a frequency based on a modulation signal at the modulation input; and
a spread spectrum modulator (SSM) having a modulation output coupled to the modulation input of the oscillator, the SSM configured to generate the modulation signal at the modulation output while adjusting a rate of change of the modulation signal based on a magnitude of the modulation signal at a boundary of a modulation time period.

2. The circuit of claim 1, wherein the clock output is a first clock output, and wherein the oscillator has a digital control input, and the SSM comprises:
a counter clock generator having a control input and a second clock output; and
a counter having a clock input and a counter output, the clock input coupled to the second clock output, and the counter output coupled to the digital control input.

3. The circuit of claim 2, wherein the counter is an up/down counter.

4. The circuit of claim 2, wherein the counter output is a first counter output, and the counter clock generator comprises:
an up/down counter having the control input and having a second counter output; and
a frequency divider having a clock input, a control input, and the second clock output, the control input of the frequency divider coupled to the second counter output.

5. The circuit of claim 2, wherein the clock input is a first clock input, and the SSM further comprises:
a first register having a first register input coupled to the counter output, having a second clock input, and having a first register output;
a second register having a second register input coupled to the counter output, having a third clock input, and having a second register output; and
a comparator having a first comparator input coupled to the first register output, having a second comparator input coupled to the second register output, and having a comparator output coupled to the control input of the counter clock generator.

6. The circuit of claim 1, wherein the SSM comprises:
a first voltage-controlled current source circuit having a first control input;
a second voltage-controlled current source circuit having a second control input; and
a sample-and-hold integrator having an input and having output, the input coupled to the modulation output, and the output of the sample-and-hold integrator coupled to the first and second control inputs.

7. The circuit of claim 6, wherein the SSM further comprises a capacitor coupled to the first and second voltage-controlled current source circuits.

8. The circuit of claim 6, wherein the sample-and-hold integrator includes a transconductance amplifier having a first amplifier input coupled to the modulation output and having a second amplifier input coupled to a reference voltage generator.

9. The circuit of claim 1, wherein the switching converter includes an isolation power converter.

10. A circuit, comprising:
a switching converter;
an oscillator having a modulation input and a clock output, the clock output coupled to the switching converter, the oscillator configured to generate a clock signal at the clock output having a frequency based on a modulation signal at the modulation input; and
a spread spectrum modulator (SSM) having a modulation output coupled to the modulation input of the oscillator, the SSM configured to generate the modulation signal at the modulation output while adjusting a rate of change of the modulation signal based on a magnitude of the modulation signal and a modulation clock signal.

11. The circuit of claim 10, wherein the clock output is a first clock output, and wherein the oscillator has a digital control input, and the SSM comprises:
a counter clock generator having a control input and a second clock output; and
a counter having a clock input and a counter output, the clock input coupled to the second clock output, and the counter output coupled to the digital control input.

12. The circuit of claim 11, wherein the counter is an up/down counter.

13. The circuit of claim 11, wherein the counter output is a first counter output, and the counter clock generator comprises:
an up/down counter having the control input and having a second counter output; and
a frequency divider having a clock input, a control input, and the second clock output, the control input of the frequency divider coupled to the second counter output.

14. The circuit of claim 11, wherein the clock input is a first clock input, and the SSM further comprises:
a first register having a first register input coupled to the counter output, having a second clock input, and having a first register output;
a second register having a second register input coupled to the counter output, having a third inverted clock input, and having a second register output; and
a comparator having a first comparator input coupled to the first register output, having a second comparator input coupled to the second register output, and having a comparator output coupled to the control input of the counter clock generator.

15. The circuit of claim 10, wherein the SSM comprises:
a first voltage-controlled current source circuit having a first control input;
a second voltage-controlled current source circuit having a second control input;
a sample-and-hold integrator having an input and having an output, the input of the sample-and-hold integrator coupled to the modulation output, and the output of the sample-and-hold integrator coupled to the first and second control inputs; and
a capacitor coupled to the first and second voltage-controlled current source circuits.

16. The circuit of claim 15, wherein the sample-and-hold integrator includes a transconductance amplifier having a first amplifier input coupled to the modulation output and having a second amplifier input coupled to a reference voltage generator.

17. A circuit, comprising:
an oscillator having a modulation input and a clock output, the oscillator configured to generate a clock signal at the clock output having a frequency based on a modulation signal at the modulation input; and
a modulator having a modulation output coupled to the modulation input of the oscillator, the modulator configured to generate the modulation signal at the modulation output while adjusting a rate of change of the modulation signal based on a magnitude of the modulation signal at a boundary of a modulation time period.

18. The circuit of claim 17, wherein the clock output is a first clock output, and wherein the oscillator has a digital control input, and the modulator comprises:
a first up/down counter having a first counter output coupled to the modulation output and having a first clock input;
a second up/down counter having a second clock input and a second counter output; and
a frequency divider having a third clock input coupled to the second counter output and having a second clock output coupled to the first clock input.

19. The circuit of claim 18, wherein the second up/down counter has a control input, and the circuit further comprises:
a first register having a first register input coupled to the first counter output and having a first register output;
a second register having a second register input coupled to the first counter output and having a second register output; and
a comparator having a first comparator input coupled to the first register output, having a second comparator input coupled to the second register output, and having a comparator output coupled to the control input of the second up/down counter.

20. The circuit of claim 17, wherein the oscillator has an analog control input, and wherein the modulator comprises:
a first voltage-controlled current source circuit;
a second voltage-controlled current source circuit; and
a capacitor coupled to the first and second voltage-controlled current source circuits and to the analog control input of the oscillator.
